(19) United States
(12) Patent Application Publication
(10) Pub. No.: US 2009/0244507 A1
(43) Pub. Date: Oct. 1, 2009

(54) OPTICAL MEMBER, LIGHT ROUTING UNIT, AND EXPOSURE APPARATUS

(75) Inventors: Yasuhisa TANI, Machida-shi (JP); Shunsuke NIISAKA, Fujisawa-shi (JP)

Correspondence Address: OLIFF & BERRIDGE, PLC, P.O. BOX 320850, ALEXANDRIA, VA, 22320-4850, US

(73) Assignee: NIKON CORPORATION, Tokyo (JP)

(21) Appl. No.: 12/392,722

(22) Filed: Feb. 25, 2009

Related U.S. Application Data
(60) Provisional application No. 61/040,356, filed on Mar. 28, 2008.

(51) Int. Cl. G03B 27/54; G02B 5/04; G03F 7/20

(52) U.S. Cl. 355/67; 359/833; 430/325

(57) ABSTRACT

Embodiment of the present invention is to provide an optical member composed of calcium fluoride (fluorite) and being capable of preventing deterioration and demonstrating a long life even in use under severe conditions. An optical member of a preferred embodiment has a base material having an entrance face into which light is incident, a total reflection face totally reflecting the incident light, and an exit face from which the totally reflected light emerges to the outside, and made of a calcium fluoride crystal; and a protecting layer to control deterioration of the total reflection face by the light, which is provided on a surface outside the total reflection face in this base material.

### CROSS-REFERENCE TO RELATED APPLICATIONS

This is a Continuation-In-Part application of Ser. No. 61/040,356 filed on Mar. 28, 2008 now pending.

### BACKGROUND OF THE INVENTION

1. Field of the Invention

Embodiments according to the present invention relates to an optical member, a light routing unit, and an exposure apparatus.

2. Related Background Art

As an exposure apparatus for performing exposure with a predetermined pattern on a wafer or the like, there is an apparatus configured to route light emitted from a light source, to an appropriate direction, let the light pass through a pattern of a mask to pattern the light, and focus the light on the wafer through the projection optical system. An ArF laser light source enabling fine exposure has been increasingly used as a light source. In the exposure apparatus adapted for the ArF laser light source, however, light-transmitting members need to have sufficient durability against the ArF laser light having high energy density. It is then known that a 45° total reflection mirror using a prism of fluorite (CaF₂) is used as a deflecting member for routing the light in the exposure apparatus (cf. International Publication WO2005/010963).

### SUMMARY OF THE INVENTION

The total reflection mirror of fluorite as described above has excellent durability against the ArF laser light, and demonstrated little deterioration of optical characteristics, for example, within a period of time shorter than or equivalent to the life of the light source. In recent years, however, efforts have been made to pursue use of the ArF laser light at higher output power, repetitive use of the exposure apparatus by replacement of only the light source, and so on; in this case, the total reflection mirror is required to be used under much severer conditions (higher power and longer term) than before. When the total reflection mirror of fluorite is used under such severer conditions, it can undergo deterioration which has never been experienced before.

The present invention has been accomplished in view of the above-described circumstances and an object of the present invention is therefore to provide an optical member capable of preventing the deterioration even in use under severe conditions and demonstrating a long life. Another object of the present invention is to provide a light routing unit and exposure apparatus using such an optical member.

The inventors studied the use of the total reflection mirror of fluorite under the severer conditions than before as described above, and found the surprising fact that after use at high power and for a long period of time, deterioration occurred in the total reflection surface which was believed to be free of influence of the light because the light should be totally reflected thereon. Based on this finding, we found that the above objects must be achieved by preventing the deterioration of the total reflection surface, thereby accomplishing the following embodiments of the present invention.

Specifically, an optical member according to embodiment of the present invention is an optical member comprising: a base material of a calcium fluoride crystal having an entrance face into which light is incident, a total reflection face totally reflecting the incident light, and an exit face from which the totally reflected light emerges to the outside; and a protecting layer to control deterioration of the total reflection face by the light, which is provided on a surface outside the total reflection face in the base material.

The optical member of the embodiment of the present invention is preferably configured as follows: the base material is a prism; the total reflection face in the base material coincides with a crystal face {100} of the calcium fluoride crystal; and, supposing that in the base material there is a virtual plane intersecting with all of the entrance face, the total reflection face, and the exit face and being perpendicular to the total reflection face, the plane coincides with a crystal face {110} of the calcium fluoride crystal. Alternatively, the optical member is preferably configured as follows: the base material is a prism; the total reflection face in the base material coincides with a crystal face {110} of the calcium fluoride crystal; and, supposing that in the base material there is a virtual plane intersecting with all of the entrance face, the total reflection face, and the exit face and being perpendicular to the total reflection face, the plane coincides with a crystal face {110} of the calcium fluoride crystal. Further, the optical member is also preferably configured as follows: the base material is a prism, the total reflection face in the base material coincides with a crystal face {110} of the calcium fluoride crystal, and supposing that in the base material there is a virtual plane intersecting with all of the entrance face, the total reflection face, and the exit face and being perpendicular to the total reflection face, the virtual plane coincides with a crystal face {100} of the calcium fluoride crystal. These virtual planes are preferably perpendicular to all of the entrance face, the total reflection face, and the exit face.

The optical member of the embodiment of the present invention is also preferably configured as follows: the protecting layer is comprised of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃.

Furthermore, the optical member of the embodiment of the present invention is preferably configured as follows: an optical thickness of the protecting layer is not less than 0.25λ nor more than 0.75λ, where λ is a wavelength of the incident light.

Embodiment according to the present invention also provides a light routing unit comprising a deflecting member to deflect a traveling direction of incident light and emit the deflected light therefrom, wherein the deflecting member is the optical member of the above embodiment of the present invention.

Furthermore, embodiment according to the present invention provides an exposure apparatus to perform exposure with light from a light source, the exposure apparatus comprising: the light routing unit of the above embodiment of the present invention; and an exposure optical system to irradiate the light from the light source having traveled via the light routing unit.

The embodiment of the present invention also provides a device manufacturing method comprising: an exposure block of applying light with a predetermined pattern to a photosensitive layer of a photosensitive substrate on which the photosensitive layer is formed, using the exposure apparatus of the above embodiment of the present invention; a development block of developing the photosensitive layer after the exposure block to form a mask layer in a shape corresponding to the pattern on the substrate; and a processing block of processing a surface of the substrate through the mask layer.

Embodiment of the present invention successfully provides the optical member comprised mainly of calcium fluoride (fluorite) and demonstrating a long life, with little deterioration even in use under severe conditions. Embodiment of the present invention also successfully provides the light routing unit and exposure apparatus using the optical member.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a perspective view schematically showing a prism of a preferred embodiment.

FIG. 2 is a drawing schematically showing a sectional structure of a prism of another embodiment.

FIG. 3 is a perspective view schematically showing a rod type integrator of another preferred embodiment.

FIG. 4 is a drawing showing a configuration of an exposure apparatus according to a preferred embodiment.

FIG. 5 is a drawing showing a configuration of a measuring device used in examples.

FIG. 6 is a graph showing changes in reflectance against pulse count of ArF laser light.

FIG. 7 is a flowchart showing blocks of manufacturing semiconductor devices.

FIG. 8 is a flowchart showing blocks of manufacturing a liquid crystal device such as a liquid crystal display device.

### DESCRIPTION OF THE PREFERRED EMBODIMENTS

The preferred embodiments of the present invention will be described below with reference to the drawings. In the description of the drawings the same elements will be denoted by the same reference symbols, without redundant description.

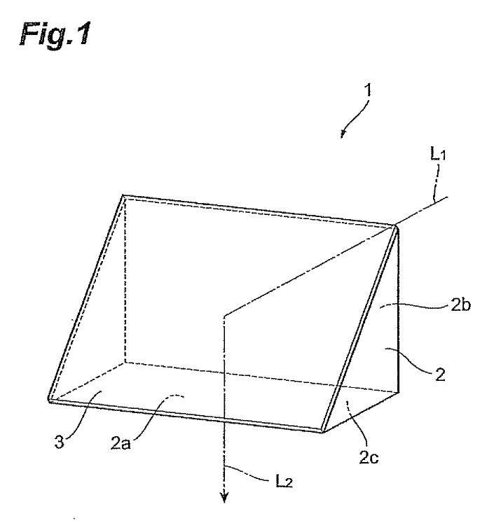

In the description hereinafter, a prism applied as a 45° total reflection mirror will be explained as an example of the optical member according to a preferred embodiment. FIG. 1 is a perspective view schematically showing the prism of the preferred embodiment. As shown in FIG. 1, the prism 1 of the present embodiment has a configuration provided with a base material 2 of a triangular prism shape and a protecting layer 3 provided on one side face in this base material 2.

The base material 2 is composed of a single crystal of calcium fluoride (CaF₂). This base material 2 has a triangular prism shape having a pair of bottom faces of a right triangle shape and three side faces connecting between the sides of these bottom faces. Of the three side faces in the base material 2, a face connecting between the hypotenuses of the bottom faces constitutes a total reflection face 2a, and the two sides adjacent to this total reflection face 2a constitute an entrance face 2b and an exit face 2c, respectively.

A protecting layer 3 is provided on a surface outside the total reflection face 2a in the base material 2. This protecting layer 3 is preferably a layer of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃. Among others, the protecting layer 3 is preferably made of a material that can prevent deterioration of the base material 2, has high durability per se, absorbs little light incident to the prism 1, and can achieve good reflectance with the prism 1. From this viewpoint, the material of the protecting layer 3 is more preferably SiO₂ or MgF₂ and particularly preferably MgF₂.

The thickness of the protecting layer 3 is preferably not less than 0.25λ (λ is a wavelength of the light incident to the prism 10) as an optical film thickness. If this optical film thickness is below 0.25λ, the protecting layer tends to fail in sufficiently preventing the deterioration of the base material 2. However, if the thickness of the protecting layer 3 is too large, it can cause reduction in reflectance; therefore, the thickness is preferably not more than 0.75λ as an optical film thickness.

There are no particular restrictions on a method of forming the protecting layer 3 on the base material 2, and it may be optionally selected as a method such as vacuum evaporation or sputtering according to the material of the protecting layer 3.

The protecting layer 3 of the material as described above is preferably formed on the total reflection face 2a only but, preferably, is not formed on the entrance face 2b and on the exit face 2c. A well-known optical thin film except for the protecting layer 3 may be formed on the entrance face 2b and on the exit face 2c. The optical thin film can be, for example, an antireflection coating or the like as described in U.S. Pat. No. 5,963,365.

When the prism 1 having the configuration as described above is used as, for example, a deflecting member to deflect a traveling direction of incident light and emit the deflected light therefrom, as shown in FIG. 1, the incident light indicated by L₁ is incident through the entrance face 2b into the interior of the prism 1 and the light travels through the interior of the prism 1 to the total reflection face 2a to be totally reflected thereon. Then the totally reflected light travels through the interior of the prism 1 to be emitted as emerging light indicated by L₂, from the exit face 2c. In this manner, the incident light L₁ is emitted as the emerging light L₂ after deflected perpendicularly by the prism 1.

When the prism 1 is used as described above, the following effect is achieved. Specifically, in the conventional case where the fluorite prism was used, for example, with the ArF laser light source as a light source, deterioration thereof rarely caused a problem heretofore because the fluorite prism has excellent durability against the ArF laser light. It was, however, found by the inventors' research that the reflectance by the fluorite prism could gradually decrease after operation of deflection for a much longer time with the use of the ArF laser light at the output power higher than before. It is assumed that in future the fluorite prism will be used at a much higher output power or for a much longer period of time or under the both conditions than in the conventional cases, and in the case of use under such conditions, the decrease in reflectance confirmed above might cause a problem of degradation of characteristics with time as the deflecting member.

Then the inventors conducted a further research as to the decrease in the reflectance of the fluorite prism and found the surprising fact that a factor to cause this decrease in reflectance was the deterioration of the total reflection surface of the fluorite prism. Since the total reflection surface totally reflects light without absorption, it is a portion that is normally considered not to deteriorate at all because of influence of the light. However, in the use under the severe conditions as described above, the total reflection surface is damaged and this is considered to be a cause of the decrease in reflectance.

The cause of the damage as described above is not always clarified yet, but it is presumed as follows according to the inventors' research: in the fluorite prism, a small amount of light leaks at the total reflection surface (such light is called evanescent light); this evanescent light induces a photochemical reaction between the base material of fluorite and components and the like adhering to the surface on the total reflection surface; this results in the damage. The damage is considered to be caused by adhesion of substances made by such photochemical reaction, to the exterior of the total reflection surface. Calculation leads to the fact that this evanescent light is stronger when the light incident to the prism is p-polarized light than when it is s-polarized light. It is, therefore, considered that influence of the damage becomes more significant, particularly, when the incident light is p-polarized light for the total reflection surface.

A conceivable technique for preventing the deterioration of the fluorite prism is, for example, a method of lowering the output power of the light source, or a method of lowering the energy density of the incident light, but these methods could fail in adequate adaptation for future increase in output power or could require change in design of exposure apparatus or the like because of increase in scale of components thereof. In contrast to it, the prism 1 having the configuration of the present embodiment is made by simply providing the protecting layer 3 of the aforementioned material or the like on the total reflection face 2a of the base material 2 of CaF₂ being the fluorite prism, whereby the deterioration possibly caused on the total reflection face 2a is adequately prevented.

Therefore, the prism 1 of the present embodiment enables the future increase in output power and resolution of the pattern and also enables adequate reduction in temporal deterioration possibly caused thereby. Since the evanescent light considered to be the cause of deterioration of the total reflection surface is prominent when the incident light is p-polarized light for the total reflection surface as described above, the prism 1 of the present embodiment is suitably applicable, particularly, to the deflecting member located at a position where p-polarized light is incident to the total reflection surface.

The calcium fluoride crystal making up the base material 2 of the prism 1 is a crystal material of the cubic crystal system, and the way of variation in a polarization state of linearly polarized light emerging therefrom differs depending upon the crystal orientation of the entrance face when linearly polarized light is made incident thereto. When the polarization state varies, the ratio of the above evanescent light also change, a deterioration of the total reflection face 2a may be promoted thereby. Therefore, if such variation in the polarization state can be stabilized, the deterioration of the total reflection face 2a can be further controlled. In order to suppress such variation in the polarization state, the calcium fluoride crystal making up the base material 2 preferably satisfies the condition as described below.

Specifically, in the prism 1, as described above, light is incident into the entrance face 2b, is reflected on the total reflection face 2a, and emerges from the exit face 2c; then, the base material 1 preferably satisfies the following condition: when a virtual plane is considered as a plane spanned by the optical axis of the incident light and the optical axis of the emerging light, the virtual plane coincides with a crystal face {100} of the calcium fluoride crystal and the total reflection face 2a coincides with a crystal face {110}. This virtual plane, in other words, is a plane intersecting with all of the entrance face 2b, the total reflection face 2a, and the exit face 2c and being perpendicular to the total reflection face 2a.

The foregoing virtual plane and the total reflection face 2a do not always have to coincide perfectly with the respective crystal faces described above, but may approximately coincide therewith. When the birefringence of the calcium fluoride and light path are considered, the crossing angle of the virtual plane or the total reflection face 2a, and above-mentioned respective crystal face of the calcium fluoride crystal is preferably within ±25 degrees, more preferably ±15 degrees. If the protecting layer 3 is provided on the total reflection face 2a in the base material 1 satisfying the above-described condition, it becomes feasible to prevent the variation in the polarization state as much as possible and to also prevent the deterioration of the total reflection face 2a as described above, thereby obtaining the prism 1 which can be stably used over long periods. From the viewpoint of achieving the same effect, the base material 1 may satisfy the following condition: the aforementioned virtual plane approximately coincides with a crystal face {110} of the calcium fluoride crystal and the total reflection face 2a approximately coincides with a crystal face {110}, or: the aforementioned virtual plane approximately coincides with a crystal face {110} of the calcium fluoride crystal and the total reflection face 2a approximately coincides with a crystal face {100}. These virtual planes are preferably perpendicular to all of the entrance face, the total reflection face, and the exit face.

Another preferred embodiment of the optical member according to the present invention will be described below.

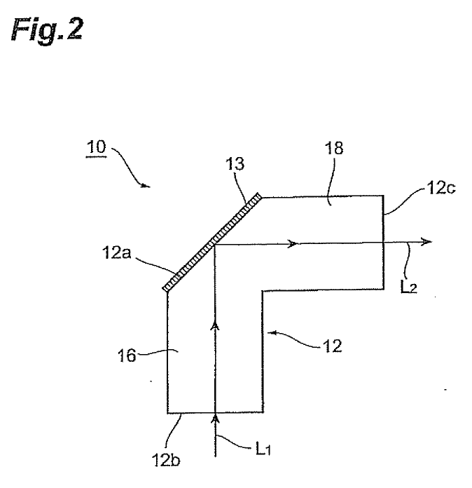

FIG. 2 is a drawing schematically showing a sectional shape of the prism of the other embodiment. The prism 10 shown in FIG. 2 has a configuration with a base material 12, and a protecting layer 13 formed on a surface outside a total reflection face 12a of this base material 12.

The base material 12 is composed of a single crystal of CaF₂ as the base material 2 in the aforementioned prism 1. The base material 12 is composed of a light lead-in portion 16 and a light lead-out portion 18 extending in directions perpendicular to each other. The two ends of this base material 12 are an entrance face 12b and an exit face 12c each perpendicular to the extending direction of the light lead-in portion 16 and the light lead-out portion 18. Outside a joint part between the light lead-in portion 16 and the light lead-out portion 18 in the base material 2, the total reflection face 12a is formed in a positional relation of 45° with each of the entrance face 12b and the exit face 12c. Although a sectional shape of the base material 12 in the direction perpendicular to FIG. 2 is not shown, it may be, for example, any one of various forms including a circle, a quadrilateral, and so on with respect to the passing direction of light described later. A protecting layer 13 is provided on the exterior surface of the total reflection face 12a of the base material 12 so as to cover the surface. A preferred configuration of the protecting layer 13 is the same as that of the protecting layer 3 in the above-described prism 1.

In the prism 10 having the above configuration, the incident light indicated by L₁ is incident through the entrance face 12b into the interior, and the light travels through the light lead-in portion 16 to the total reflection face 12a to be totally reflected thereon. Then the totally reflected light travels through the light lead-out portion 18 to be emitted as emerging light indicated by L₂, from the exit face 12c. In this manner, the incident light L₁ can be deflected by the prism 10 to be the emerging light L₂ in the perpendicular direction. Since the prism 10 of this form is also provided with the protecting layer 13 on the exterior of the total reflection face 12a, the total reflection face 12a is very unlikely to deteriorate even in repetitive use under the conditions of high output and long term and thus the prism has a long life.

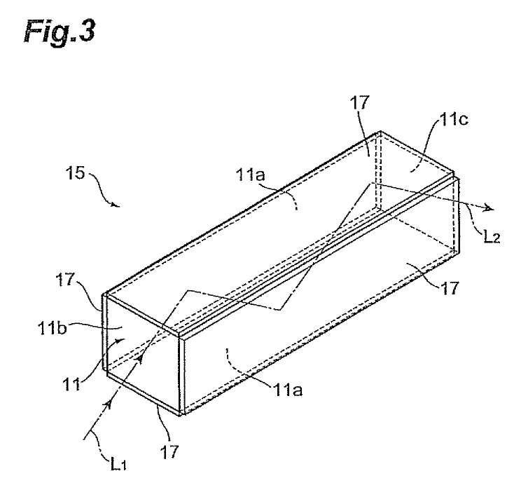

The optical member of the present embodiment may also be constructed in a form other than the above-described prisms. An example of the optical member except for the prisms can be, for example, a rod type integrator. FIG. 3 is a perspective view showing the rod type integrator of a preferred embodiment. The rod type integrator 15 shown in FIG. 3 has a configuration with a base material 11 of a rectangular prism shape, and a protecting layer 17 provided on the exterior of four side faces in this base material 11.

The base material 11 is composed of a single crystal of CaF₂ as the base material 2 in the aforementioned prism 1. A pair of side faces opposed to each other in this base material 11 constitute total reflection faces 11a and the two end faces in the base material 11 are an entrance face 11b and an exit face 11c, respectively. The protecting layer 17 is provided so as to cover all the side faces including the pair of total reflection faces 11a. A preferred configuration of this protecting layer 17 is the same as that of the protecting layer 3 in the aforementioned prism 1.

In this rod type integrator 15, the incident light indicated by L₁ is incident at a predetermined angle through the entrance face 11b into the interior, the light travels through the interior of the base material 11 while repeatedly totally reflected by the opposed total reflection faces 11a, and the light is emitted as emerging light indicated by L₂, from the exit face 11c. Since this rod type integrator 15 is configured to repeatedly reflect the light incident through the entrance face 11b (incident light L₁) inside, it provides homogenized light (emerging light L₂) on the exit face. Since this rod type integrator 15 also has the protecting layer 17 formed on the exterior of the total reflection faces 11a, the total reflection faces 11a are also very unlikely to deteriorate even in repetitive use under the conditions of high output and long term and thus it has a long life.

The below will describe a light routing unit using the optical member of the present embodiment and an exposure apparatus provided therewith. The example described below is one using the prism 1 of the above-described embodiment.

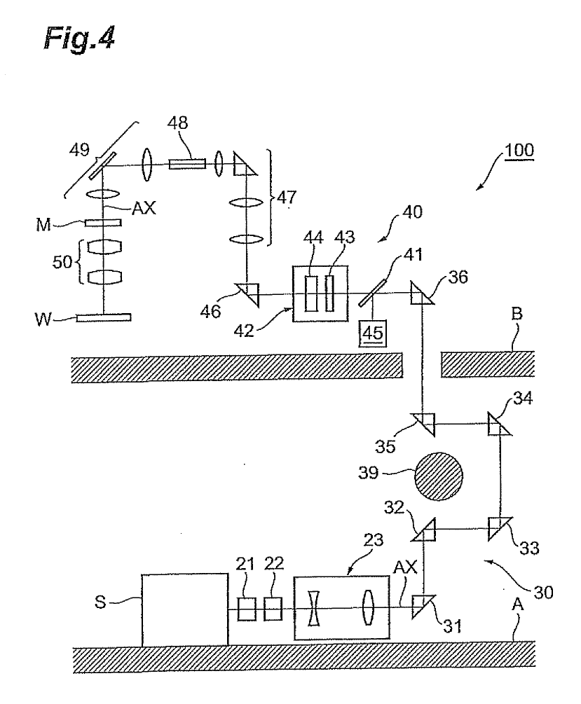

FIG. 4 is a drawing showing a configuration of the exposure apparatus according to a preferred embodiment. The exposure apparatus 100 shown in FIG. 4 is configured to apply light from a light source S installed on a floorboard A of a lower floor and emitting ArF laser light, onto a wafer W (substrate) set on a floorboard B of an upper floor. There are no particular restrictions on the light source S applied to the exposure apparatus 100, but an ArF excimer laser light source (wavelength 193 mm) is preferably applicable because the life becomes prominently enhanced by the optical member of the embodiment (e.g., the aforementioned prism 10). An example of the wafer W is a silicon wafer.

The exposure apparatus 100 is composed of a light routing unit 30, an illumination optical system 40, and a projection optical system 50. The light routing unit 30 in this exposure apparatus 100 has the following members in the order of passage of the light from the light source S: a pair of angle-deviating prisms 21, a plane-parallel plate 22, a beam expander 23, and prisms 31, 32, 33, 34, 35, and 36.

In the light routing unit 30, each of these prisms 31-36 is composed of the optical member of the above embodiment (e.g. the prism 1 in the aforementioned preferred embodiment). Specifically, each prism 31-36 is arranged so that a face corresponding to the entrance face 2b of the prism 1 faces the light incidence side.

The illumination optical system 40 is arranged after the light routing unit 30, has a half mirror 41, a polarization state switch 42 having a half wave plate 43 and a depolarizer 44 in order, a prism 46, a lens system 47, a rod type integrator 48, and a lens system 49 in the order of passage of the light, and is configured to apply the light from the light source S having traveled via the light routing unit 30, onto a mask M arranged after the illumination optical system 40. The illumination optical system 40 further has a positional deviation/inclination detector 45 for detecting positional deviation and inclination of light reflected by the half mirror 41.

Furthermore, the projection optical system 50 is arranged after the mask M and is composed of a plurality of lenses. This projection optical system 50 projects to the wafer W the light radiated from the illumination optical system 40 and patterned through the mask M. An exposure optical system is composed of these illumination optical system 40 and projection optical system 50. Namely, this exposure optical system is able to apply to the wafer W the light with the predetermined pattern corresponding to the mask M, based on the light from the light source S having traveled via the light routing unit 30.

In the exposure optical system composed of the illumination optical system 40 and the projection optical system 50, each of the prism 46 and the rod type integrator 48 is composed of the optical member of the above embodiment. Specifically, for example, the prism 46 is preferably composed of the prism 1 in the aforementioned embodiment and the rod type integrator 48 is preferably composed of the rod type integrator 15 in the aforementioned embodiment.

The above-described exposure apparatus 100 is constructed using the optical members according to the embodiments of the present invention such as the prism 1 and the rod type integrator 15, and in the usage of these, the optical members of the above embodiment are desirably used in an environment from which oxygen and water is removed, in order to prevent deterioration. Furthermore, the optical members are preferably used in an atmosphere that does not decrease the transmittance at the wavelength of ArF laser, specifically, in an atmosphere of inert gas such as nitrogen gas. For satisfying such a condition, for example, the environment in which the optical members are arranged in the light routing unit 30 is preferably a nitrogen gas atmosphere. For that, for example, the optical members may be arranged in a space replaced with nitrogen gas and thereafter hermetically closed, or they may be kept in a state in which nitrogen gas always flows.

An exposure method with the above-described exposure apparatus 100 is as follows. Specifically, the light (beam) emitted from the light source S first travels through the pair of angle-deviating prisms 21 and the plane-parallel plate 22. At least one of the pair of angle-deviating prisms 21 is arranged as rotatable around the optical axis AX of the incident light. For this reason, it is possible to adjust an angle of the parallel beam relative to this optical axis AX by rotating the pair of angle-deviating prisms 21 relative to each other around the optical axis AX. Namely, the pair of angle-deviating prisms 21 constitute a beam angle adjuster to adjust the angle of the parallel beam supplied from the light source S, relative to the optical axis AX.

The plane-parallel plate 22 is rotatable around two axes orthogonal to each other in a plane perpendicular to the optical axis AX. Therefore, when the plane-parallel plate 22 is inclined relative to the optical axis AX by rotating it around each of the axes, the parallel beam from the angle-deviating prisms 21 can be moved in parallel to the optical axis AX. Namely, the plane-parallel plate 22 constitutes a beam parallel movement device to move the parallel beam supplied from the light source S, in parallel to the optical axis AX.

The parallel beam from the plane-parallel plate 22 is then incident into the beam expander 23 and is enlarged and shaped into a parallel beam with a predetermined sectional shape by this beam expander 23.

The parallel beam enlarged and shaped by the beam expander 23 is first deflected into the vertical direction by the prism 31. The deflected beam is further successively reflected by the prisms 32, 33, 34, and 35 and thereafter passes through an opening provided in the floorboard B of the upper floor to enter the prism 36. In this manner, the light (beam) emitted from the light source S on the lower floor is guided to the upper floor by the plurality of prisms, while bypassing, for example, piping 39 for supply of pure water, ventilation, and so on.

The beam incident to the prism 36 is deflected again into the horizontal direction by this prism 36 and is then incident to the half mirror 41. The beam reflected by this half mirror 41 is guided to the positional deviation/inclination detector 45. On the other hand, the beam transmitted by the half mirror 41 is guided to the polarization state switch 42. The positional deviation/inclination detector 45 detects the positional deviation and inclination of the parallel beam incident to the polarization state switch 42, relative to the optical axis AX. Then, based on this information, the polarization state switch 42 appropriately adjusts the polarization state of the incident beam.

The beam from the polarization state switch 42 is deflected into the vertical direction by the prism 46 and thereafter travels through the lens system 47 to enter the rod type integrator 48. The beam homogenized by this rod type integrator 48 travels through the mask M with the predetermined pattern thereon to be patterned by the predetermined pattern. The beam through the mask M travels through the projection optical system 50 to project an image corresponding to the pattern of the mask onto the wafer W. In this way, the wafer W is exposed to the predetermined pattern shape.

Since the exposure apparatus 100 of the present embodiment is provided with the light routing unit 30 as described above, it is able to apply the light from the light source S to the wafer W set on the floor different from that of the light source S or the like. Since the light routing unit 30 in this exposure apparatus 100 is provided with the optical members of the embodiment (e.g., the prisms 1 in the aforementioned embodiment) as the deflecting members to deflect light, it causes little reduction in reflectance by the deflecting members (prisms 31-36), for example, even if the light emitted from the light source S has high power or even if it is used for an extremely long period with replacement of the light source S or the like; therefore, it can have high reliability and a long life.

The exposure apparatus or the light routing unit of the embodiment of the present invention does not always have to be limited to the configuration of the embodiment described above, but can be modified according to circumstances. Specifically, the aforementioned light routing unit 30 was the one having the angle-deviating prisms 21, plane-parallel plate 22, beam expander 23, and prisms 31-36. However, the light routing unit of the embodiment of the present invention may be one provided with at least the optical member of the above embodiment as a deflecting member. Therefore, for example, the light routing unit of the embodiment of the present invention can be one provided with only one of the prisms 31-36. However, in order to deflect the light from the light source into a desired direction as in the above embodiment, the light routing unit is preferably one provided with at least two optical members as deflecting members.

The exposure optical system (illumination optical system 40 and projection optical system 50) in the exposure apparatus 100 is not limited to that in the above embodiment, either, and may be any system capable of patterning and irradiating the light from the light routing unit. For example, the exposure optical system can be composed of a mask only. Furthermore, the projection optical system 50 is not limited to that in the above embodiment, either, as long as it has the function to project the light from the illumination optical system onto the wafer or the like.

In the light routing unit 30 every one of the prisms 31-36 was composed of the optical member (prism 1) of the above embodiment, but the light routing unit 30 may be constructed in a structure in which at least one of them is composed of the optical member of the embodiment. For example, since the optical member of the embodiment of the present invention can effectively prevent the deterioration which is likely to occur in the case where p-polarized light is incident to the total reflection surface as described above, the light routing unit 30 may be constructed in a configuration wherein the optical member of the embodiment of the present invention is applied to each deflecting member into which p-polarized light is incident and wherein the conventional optical member without the protecting layer (e.g., only the base material 2) is applied to each deflecting member into which s-polarized light is incident to the total reflection surface.

The below will describe the preferred embodiments of the device manufacturing method using the exposure apparatus as described above.

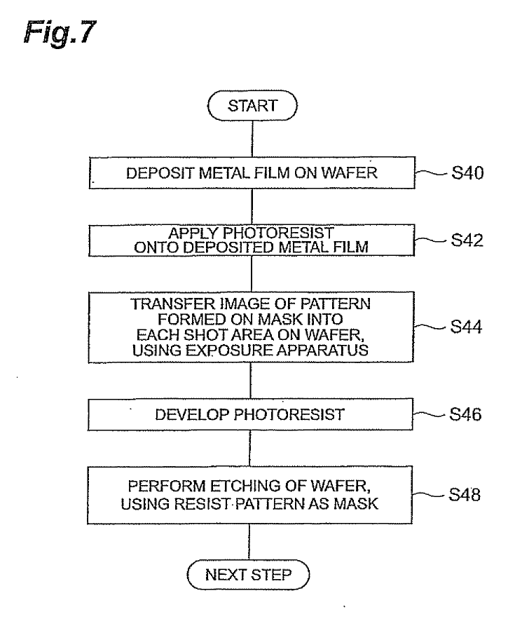

First, FIG. 7 is a flowchart showing blocks of manufacturing semiconductor devices. As shown in FIG. 7, the semiconductor device manufacturing blocks include depositing a metal film on a wafer to become a substrate of semiconductor devices (block S40), and applying and forming a photoresist (photosensitive layer) being a photosensitive material, on the deposited metal film (block S42). The subsequent block is to perform exposure using the exposure apparatus of the foregoing embodiment to transfer a pattern formed on a reticle (mask), for example, into each shot area on the wafer (block S44: exposure block).

The next block is to perform development of the photoresist onto which the pattern is transferred, on the wafer after completion of the transfer (block S46: development block). The following block is to perform processing such as etching for the surface of the wafer, using the resist pattern generated on the surface of the wafer by the development of the photoresist, as a mask (block S48: processing block).

The resist pattern herein is a photoresist layer in which depressions and projections are made in the shape corresponding to the pattern transferred by the exposure apparatus and in which the depressions penetrate the photoresist layer. block S48 is to process the surface of the wafer W through this resist pattern. The processing carried out in this block S48 is at least either etching of the surface of the wafer or deposition of a metal film or the like thereon. In block S44 the exposure apparatus performs the transfer of the pattern using the wafer coated with the photoresist, as a photosensitive substrate.

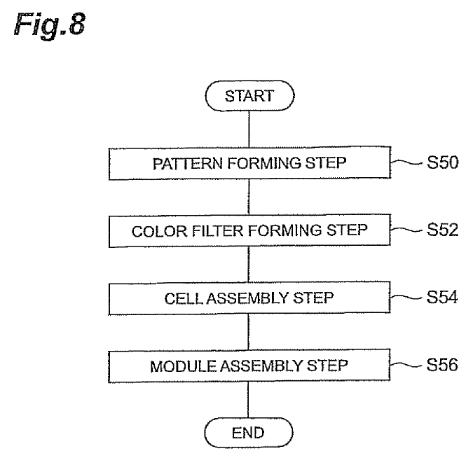

FIG. 8 is a flowchart showing blocks of manufacturing a liquid crystal device such as a liquid crystal display device. As shown in FIG. 8, the liquid crystal device manufacturing blocks include sequentially carrying out a pattern forming block (block S50), a color filter forming block (block S52), a cell assembly block (block S54), and a module assembly block (block S56).

First, the pattern forming block of block S50 is to form predetermined patterns such as a circuit pattern and an electrode pattern on a glass substrate coated with a photoresist (photosensitive substrate), using the exposure apparatus as in the aforementioned embodiment. This pattern forming block includes an exposure block of transferring a pattern onto the photoresist layer, using the exposure apparatus, a development block of developing the glass substrate (photoresist layer) on which the pattern has been transferred, to form a resist pattern (mask layer) in a shape corresponding to the pattern, and a processing block of processing the surface of the glass substrate through the developed resist pattern, as described above.

The next color filter forming block of block S52 is to form a color filter in a configuration wherein a large number of sets of three dots corresponding to R (red), G (green), and B (blue) are arrayed in a matrix pattern, or in a configuration wherein a plurality of sets of three stripe filters of R, G, and B are arrayed along a horizontal scan direction.

The subsequent cell assembly block of block S54 is to assemble a liquid crystal panel (liquid crystal cell), using the glass substrate with the predetermined pattern formed in block S50 and the color filter formed in block S52. Specifically, for example, the color filter is arranged opposite to the glass substrate and a liquid crystal is poured into between these to form the liquid crystal panel.

The subsequent module assembly block of block S56 is to attach various components such as electric circuits and backlights for display operation of the liquid crystal panel, to the liquid crystal panel assembled in block S54, thereby completing a liquid crystal device.

The exposure apparatus of the embodiment of the present invention is applicable to the manufacturing methods of devices as described above, but is not limited to the application to these device manufacturing methods. For example, the exposure apparatus of the embodiment is widely applicable to the exposure apparatus for manufacturing the display devices such as the liquid crystal display devices or plasma displays formed with rectangular glass plates, or to the exposure apparatus for manufacturing various devices such as imaging devices (CCDs and the like), micromachines, thin-film magnetic heads, and DNA chips. The exposure apparatus of the embodiment is also applicable, for example, to an exposure block in photolithography for manufacture of masks (photomask, reticle, etc.) on which a mask pattern used in manufacture of various devices is formed.

### EXAMPLES

The embodiment of the present invention will be described below in more detail with examples thereof, but it should be noted that the present invention is by no means intended to be limited to these examples.

### [Formation of Prism (Optical Member)]

### Examples 1 and 2

First, the base material was formed of a single crystal of calcium fluoride (CaF₂) and in a triangular prism shape in which the shape of the bottom surfaces was a rectangular equilateral triangle. Then a film of magnesium fluoride (MgF₂) was formed as a protecting layer on a side face (total reflection face) connecting between the hypotenuses of the bottom faces in the base material, by vacuum evaporation. On this occasion, samples were prepared as a prism of Example 1 or as a prism of Example 2 in which the thickness of the protecting layer was 0.5λ or 0.75λ (where λ is 193 nm being the wavelength of the ArF laser light) as an optical film thickness.

### Comparative Example 1

The base material was made of a single crystal of calcium fluoride (CaF₂) and in a triangular prism shape in which the shape of the bottom faces was a rectangular equilateral triangle, and was not provided with the protecting layer (i.e., only the base material), as a sample of a prism in Comparative Example 1.

### [Evaluation of Durability]

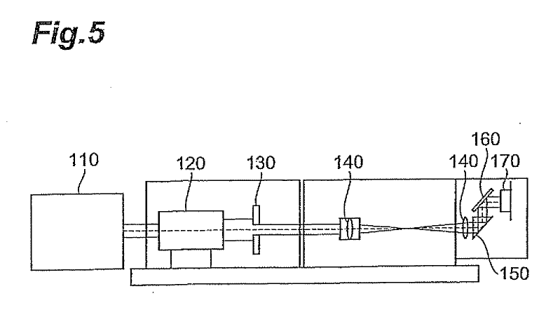

A change in reflectance against operating time (pulse count of incident light) was measured by a method described below, using each of the prisms of Examples 1 and 2 and Comparative Example 1 as a deflecting member. Specifically, a device for the measurement was prepared as a device in which the following members were arranged in the order named from the light source side, as shown in FIG. 5: ArF excimer laser light source 110, zoom lens 120, stop 130, condensing member 140, sample 150 of the prism of the example or comparative example, half mirror 160, and monitor 170. On this occasion, the prism was arranged so that light incident into the interior thereof was reflected into the vertical direction by the total reflection face.

Using this device, the light was guided from the light source 110 through the zoom lens 120, stop 130, and condensing member 140 and was deflected perpendicularly by the prism. The light from this prism was deflected into the horizontal direction by the half mirror 160 to be guided to the monitor, and the reflectance by the prism was measured with time by this monitor. The reflectance was calculated as relative reflectance (%) with respect to the reflectance at a start of operation as 100%. On this occasion, the deflecting member interposed between the sample 150 and the monitor 170 was the half mirror, and an unrepresented shutter was provided between the half mirror 160 and the sample 150, whereby the light was incident to the half mirror 160 only during the measurement of reflectance. This configuration eliminated influence of the optical member interposed between the sample 150 and the monitor 170, on reflectance.

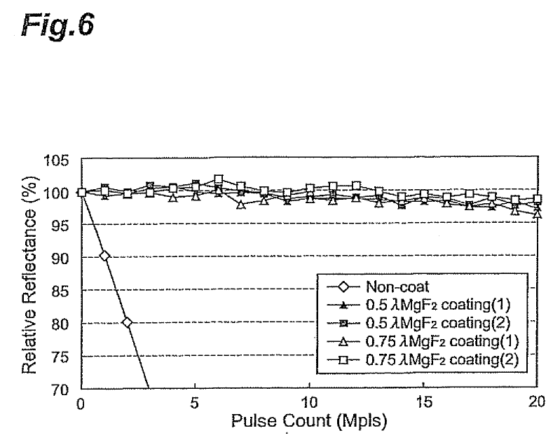

FIG. 6 shows the results of the measurement using the samples of the prisms of the examples or the comparative example. FIG. 6 is a graph showing changes of reflectance against pulse count of ArF laser light. FIG. 6 shows the results of the measurement carried out with two samples prepared for each of Examples 1 and 2.

As apparent from the results shown in FIG. 6, it was confirmed that the prisms (optical members) of the examples with the protecting layer of MgF₂ on the total reflection face were able to maintain the reflectance over a long period of time, when compared with the prism without the protecting layer.

What is claimed is:

1. An optical member comprising:
a base material of a calcium fluoride crystal having an entrance face into which light is incident, a total reflection face totally reflecting the incident light, and an exit face from which the totally reflected light emerges to the outside; and
a protecting layer to control deterioration of the total reflection face by the light, which is provided on a surface outside the total reflection face in the base material.

2. The optical member according to claim 1,
wherein the base material is a prism,
wherein the total reflection face in the base material coincides with a crystal face {100} of the calcium fluoride crystal, and
wherein, supposing that in the base material there is a virtual plane intersecting with all of the entrance face, the total reflection face, and the exit face and being perpendicular to the total reflection face, the virtual plane coincides with a crystal face {110} of the calcium fluoride crystal.

3. The optical member according to claim 2,
wherein, the virtual plane is perpendicular to all of the entrance face, the total reflection face, and the exit face.

4. The optical member according to claim 1,
wherein the base material is a prism,
wherein the total reflection face in the base material coincides with a crystal face {110} of the calcium fluoride crystal, and
wherein, supposing that in the base material there is a virtual plane intersecting with all of the entrance face, the total reflection face, and the exit face and being perpendicular to the total reflection face, the virtual plane coincides with a crystal face {110} of the calcium fluoride crystal.

5. The optical member according to claim 4,
wherein, the virtual plane is perpendicular to all of the entrance face, the total reflection face, and the exit face.

6. The optical member according to claim 1,
wherein the base material is a prism,
wherein the total reflection face in the base material coincides with a crystal face {110} of the calcium fluoride crystal, and
wherein, supposing that in the base material there is a virtual plane intersecting with all of the entrance face, the total reflection face, and the exit face and being perpendicular to the total reflection face, the virtual plane coincides with a crystal face {100} of the calcium fluoride crystal.

7. The optical member according to claim 6,
wherein, the virtual plane is perpendicular to all of the entrance face, the total reflection face, and the exit face.

8. The optical member according to claim 1, wherein the protecting layer is comprised of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃.

9. The optical member according to claim 2, wherein the protecting layer is comprised of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃.

10. The optical member according to claim 4, wherein the protecting layer is comprised of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃.

11. The optical member according to claim 6, wherein the protecting layer is comprised of at least one material selected from the group consisting of SiO₂, Al₂O₃, MgF₂, AlF₃, Na₃AlF₆, CeF₃, LiF, LaF₃, NdF₃, SmF₃, YbF₃, YF₃, NaF, and GdF₃.

12. The optical member according to claim 1, wherein an optical thickness of the protecting layer is not less than 0.25λ nor more than 0.75λ, where λ is a wavelength of the incident light.

13. The optical member according to claim 2, wherein an optical thickness of the protecting layer is not less than 0.25λ nor more than 0.75λ, where λ is a wavelength of the incident light.

14. The optical member according to claim 4, wherein an optical thickness of the protecting layer is not less than 0.25λ nor more than 0.75λ, where λ is a wavelength of the incident light.

15. The optical member according to claim 6, wherein an optical thickness of the protecting layer is not less than 0.25λ nor more than 0.75λ, where λ is a wavelength of the incident light.

16. A light routing unit comprising a deflecting member to deflect a traveling direction of incident light and emit the deflected light therefrom,
wherein the deflecting member is the optical member as set forth in claim 1.

17. An exposure apparatus to perform exposure with light from a light source, the exposure apparatus comprising:
the light routing unit as set forth in claim 16; and
an exposure optical system to irradiate the light from the light source having traveled via the light routing unit.

18. A device manufacturing method comprising:
an exposure block of applying light with a predetermined pattern to a photosensitive layer of a photosensitive substrate that the photosensitive layer is formed on a substrate, using the exposure apparatus as set forth in claim 17;
a development block of developing the photosensitive layer after the exposure block to form a mask layer in a shape corresponding to the pattern on the substrate; and
a processing block of processing a surface of the substrate through the mask layer.
